(19) United States
(12) Patent Application Publication
(10) Pub. No.: US 2020/0203153 A1
(43) Pub. Date: Jun. 25, 2020

(54) ANTI-REFLECTION LAYER FOR SEMICONDUCTOR STRCUTURE

(71) Applicant: XIA TAI XIN SEMICONDUCTOR (QING DAO) LTD., Qingdao (CN)

(72) Inventors: JEE-HOON KIM, Singapore (SG); HYUNYOUNG KIM, Singapore (SG); SUNGSOO BYEON, Singapore (SG)

(21) Appl. No.: 16/663,374

(22) Filed: Oct. 25, 2019

Related U.S. Application Data
(60) Provisional application No. 62/778,923, filed on Dec. 13, 2018.

(51) Int. Cl. H01L 21/027; G03F 7/09; H01L 21/02

(52) U.S. Cl. CPC H01L 21/0276; G03F 7/091; H01L 21/02274; H01L 21/0217; H01L 21/02167

(57) ABSTRACT

A semiconductor structure is disclosed. The semiconductor structure includes a base layer, an anti-reflection layer having a plurality of elements and in physical contact with the base layer, and a photoresist layer disposed on the anti-reflection layer. The anti-reflection layer has a refractive index (n) ranging between about 2.2 to about 5.0 and an extinction coefficient (k) ranging between about 2.0 to about 3.0. In this way, deformation during etching of the semiconductor structure cause by light reflection is prevented.

### CROSS-REFERENCES TO RELATED APPLICATIONS

This application claims the benefit of U.S. Provisional Patent Application No. 62/777,8923 filed on Dec. 13, 2018, which is hereby incorporated by reference herein and made a part of specification.

### BACKGROUND

### 1. Field

The present disclosure generally relates to semiconductor structure, and more particularly, semiconductor structure having an anti-reflection layer that prevents deformation during etching process.

### 2. Related Art

When highly reflective layer is used for etching process of a semiconductor structure, the light during lithography process passes through a photoresist layer and is reflected by the highly reflective layer. The reflected light exposes the photoresist layer outside of the pattern to the light. Thus, the accuracy of the etching process of the semiconductor structure is low.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a flowchart of a method of forming a semiconductor structure according to some embodiments of the instant disclosure;

FIG. 2A-2C illustrates a cross sectional view of a semiconductor structure according to some embodiments of the instant disclosure; and

FIG. 3A-3C illustrates a cross sectional view of different types of anti-reflection layer of a semiconductor structure according to some embodiments of the instant disclosure.

### DETAILED DESCRIPTION

The present disclosure will now be described more fully hereinafter with reference to the accompanying drawings, in which exemplary embodiments of the disclosure are shown. This disclosure may, however, be embodied in many different forms and should not be construed as limited to the exemplary embodiments set forth herein. Rather, these exemplary embodiments are provided so that this disclosure will be thorough and complete, and will fully convey the scope of the disclosure to those skilled in the art. Like reference numerals refer to like elements throughout.

The terminology used herein is for the purpose of describing particular exemplary embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

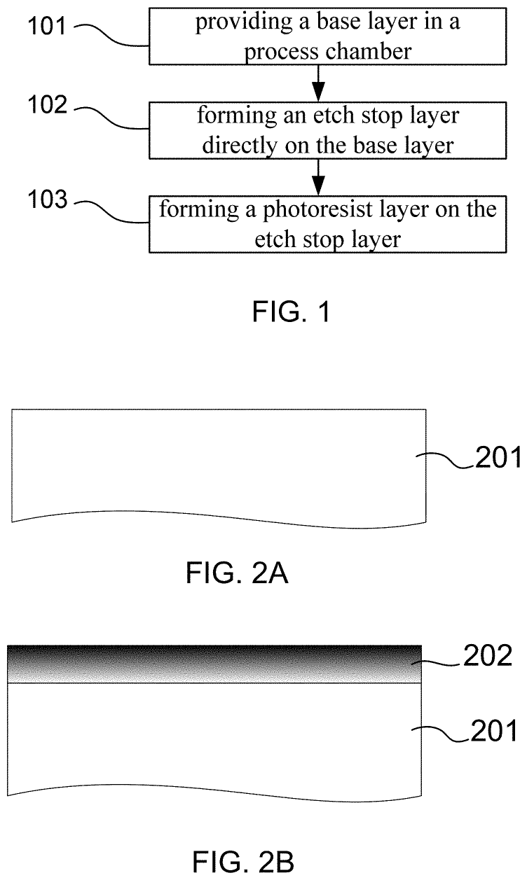

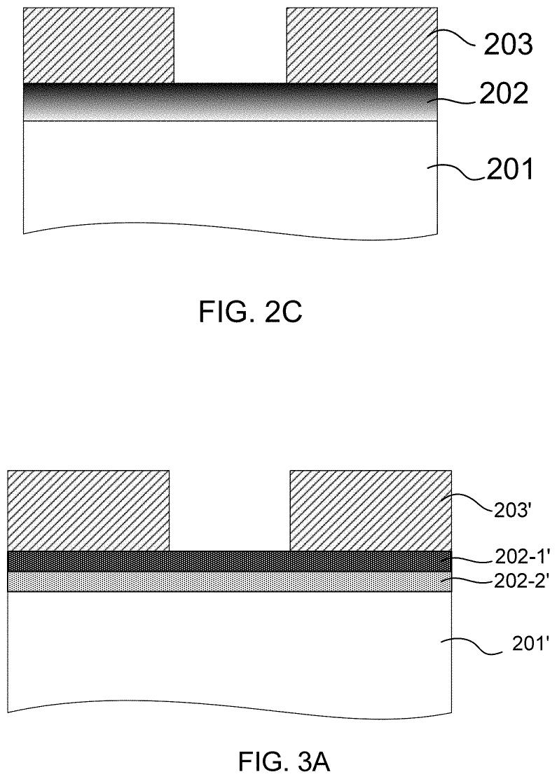

FIG. 1 illustrates a flowchart of a method of forming a semiconductor structure according to some embodiments of the instant disclosure. FIG. 2A-2C illustrates a cross sectional view of a semiconductor structure according to some embodiments of the instant disclosure. FIG. 2A-2C corresponds to each process disclosed in FIG. 1. The method includes providing a base layer in a process chamber (101), forming an anti-reflection layer directly on the base layer (102), and forming a photoresist layer on the anti-reflection layer (103). As shown in FIG. 2A, a base layer is in a process chamber. In some embodiments, the base layer 201 includes silicon. Alternatively, the base layer 201 may include germanium, silicon germanium, gallium arsenide or other appropriate semiconductor materials. Also alternatively, the base layer 201 may include at least one of an epitaxial layer, a silicon layer, and a silicon dioxide layer.

As shown in FIG. 2B, an anti-reflection layer 202 is formed directly on the base layer 201. The anti-reflection layer 202 are formed using Plasma Enhanced Chemical Vapor Deposition (PECVD). In some embodiments, the anti-reflection layer 202 has a refractive index (n) ranging between about 2.2 to about 5.0. In some embodiments, the anti-reflection layer 202 has a refractive index (n) ranging between about 3.0 to about 4.0. In some embodiments, the anti-reflection layer 202 has a refractive index (n) ranging between about 4.0 to about 5.0. In some embodiments, the anti-reflection layer 202 has a refractive index (n) ranging between about 3.0 to about 5.0. In some embodiments, the anti-reflection layer 202 has an extinction coefficient (k) ranging between about 2.0 to about 3.0. In some embodiments, the anti-reflection layer 202 has a plurality of elements. The plurality of elements includes Silicon (Si) element and Nitrogen (N) element. In some embodiments, the plurality of elements further includes Carbon (C). At least one of the plurality of elements is in gradient concentration along a thickness of the anti-reflection layer. In some embodiments, the anti-reflection layer 202 is an organic-inorganic hybrid layer, an organic layer, or an inorganic layer, such as SiN, SiOC or SiCN.

In some embodiments, when forming the anti-reflection layer 202, the process includes providing a silicon (Si) source to the process chamber, providing a nitrogen (N) source to the process chamber, and providing a Carbon (C) source to the process chamber. Silicon (Si) concentration controls the refractive index of the anti-reflection layer 202 and Carbon (C) controls the dielectric coefficient (low k) of the anti-reflection layer 202. The dielectric coefficient controls the etch resistance of the anti-reflection layer 202. When the Carbon (C) concentration increases, the dielectric coefficient of the anti-reflection layer 202 increases. The silicon (Si), Nitrogen (N), and Carbon (C) may be introduced to the film using at least one of the Tetraethyl Orthosilicate (TEOS), Dichlorosilane (DCS), Ammonia (NH₃), Nitrogen (N2), and Hydrocarbon gas.

In some embodiments, a percentage of the Nitrogen (N) source within the process chamber changes along time. In some embodiments, the percentage of the Nitrogen (N) source within the process chamber increases along time to form the anti-reflection layer 202 having a concentration of the Nitrogen (N) element closest to the base layer 201 be zero and increases as the anti-reflection layer 202 extends away from the base layer 201. In some embodiments, the percentage of the Nitrogen (N) source within the process chamber decreases along time to form the anti-reflection layer 202 having a concentration of the Nitrogen (N) element decrease as the anti-reflection layer 202 extends away from the base layer 201.

In some embodiments, a percentage of the silicon (Si) source within the process chamber changes along time. In some embodiments, the percentage of the silicon (Si) source within the process chamber increases along time to form the anti-reflection layer 202 having a concentration of the silicon (Si) element closest to the base layer 201 be zero and increases as the anti-reflection layer 202 extends away from the base layer 201. In some embodiments, the percentage of the silicon (Si) source within the process chamber decreases along time to form the anti-reflection layer 202 having a concentration of the silicon (Si) element decrease as the anti-reflection layer 202 extends away from the base layer 201.

In some embodiments, a percentage of the Carbon (C) source within the process chamber changes along time. In some embodiments, the percentage of the Carbon (C) source within the process chamber increases along time to form the anti-reflection layer 202 having a concentration of the Carbon (C) element closest to the base layer 201 be zero and increases as the anti-reflection layer 202 extends away from the base layer 201. In some embodiments, the percentage of the Carbon (C) source within the process chamber decreases along time to form the anti-reflection layer 202 having a concentration of the Carbon (C) element decrease as the anti-reflection layer 202 extends away from the base layer 201.

In some embodiments, when forming the anti-reflection layer 202, the process includes forming a SiₓC_{y}N_{z} compound layer over the base layer and forming a SiₐN_{b} compound layer over the base layer. The values of a, b, x, y, and z are stoichiometric ratio of elements in the SiₓC_{y}N_{z} compound layer and the SiₐN_{b} compound layer, and the values of a, b, x, y, and z range from 0 to about 50.

As shown in FIG. 2C, a photoresist layer 203 is formed on the anti-reflection layer 202. The photoresist layer 203 may be etched to form a pattern. When forming the pattern, the photoresist layer 203 is exposed to a light having a short wavelength and/or a long wavelength longer than the short wavelength. In some embodiments, the anti-reflection layer 202 is responsive to the short wavelength as well. The light passes through a mask having the same pattern as the pattern to be formed on the photoresist layer 203. When the photoresist layer 203 is exposed to the light passing through the mask, the area of the photoresist layer 203 exposed to the light is equivalent to the pattern to be formed on the photoresist layer 203. To prevent the photoresist layer 203 from being etched exceeding the area of the desired pattern, the anti-reflection layer 202 used is an ant-reflection layer that prevents the light from being reflected through the photoresist layer 203 at an angle and outward from the area of the desired pattern.

In other words, the semiconductor structure shown in FIG. 2C includes a base layer 201; an anti-reflection layer 202 having a plurality of elements and in physical contact with the base layer 201; and a photoresist layer 203 disposed on the anti-reflection layer 202. The plurality of elements includes Silicon (Si) element and Nitrogen (N) element. In some embodiments, the plurality of elements further includes Carbon (C). At least one of the plurality of elements is in gradient concentration along a thickness of the anti-reflection layer 202.

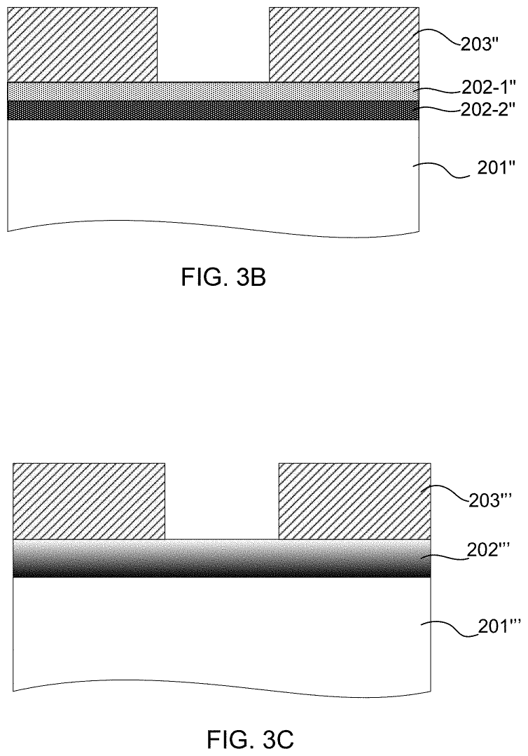

FIG. 3A-3C illustrates a cross sectional view of different types of anti-reflection layer of a semiconductor structure according to some embodiments of the instant disclosure. FIG. 2C and FIG. 3C shows anti-reflection layers 202 and 202′″ having elements at gradient concentration. FIG. 2C shows an anti-reflection layer 202 where one or more of the plurality of elements starts at least amount (light shade) and gradually increases (dark shade) as the anti-reflection layer extends away from the base layer 201. FIG. 3C shows an anti-reflection layer 202′″ where one or more of the plurality of elements starts at most amount (dark shade) and gradually decreases (light shade) as the anti-reflection layer extends away from the base layer 201′″. The gradient does not decrease the refractive index of the anti-reflection layer but improves on the attachment to the substrate or dielectric layer.

In some embodiments, a concentration of the Silicon (Si) closest to the base layer is zero and increases as the anti-reflection layer extends away from the base layer. In some embodiments, a concentration of the Silicon (Si) element farthest from the base layer is zero and increases as the anti-reflection layer extends into the base layer.

In some embodiments, a concentration of the Nitrogen (N) closest to the base layer is zero and increases as the anti-reflection layer extends away from the base layer. In some embodiments, a concentration of the Nitrogen (N) element farthest from the base layer is zero and increases as the anti-reflection layer extends into the base layer.

In some embodiments, a concentration of the Carbon (C) closest to the base layer is zero and increases as the anti-reflection layer extends away from the base layer. In some embodiments, a concentration of the Carbon (C) element farthest from the base layer is zero and increases as the anti-reflection layer extends into the base layer.

In some embodiments, a ratio between Silicon (Si) and the Carbon (C) (Si:C ratio) ranges from about 1:2 to about 2:1. The Silicon:Carbon Ratio may be varied according to RF power, substrate temperature, and gas mixture. In some embodiments, RF power ranges from 300 W to 1000 W (1:1 ratio formed at 700 W). In some embodiments, substrate temperature ranges about 50° C. to 500° C.

FIGS. 3A and 3B shows an anti-reflection layer having a SiₓC_{y}N_{z} compound layer 202-1′ and 202-1″ and a SiₐN_{b} compound layer 202-2′ and 202-2″. In FIG. 3A, the SiₐN_{b} compound layer 202-2′ is disposed on the base layer 201′ and the SiₓC_{y}N_{z} compound layer 202-1′ is disposed on the SiₐN_{b} compound layer 202-2′. In FIG. 3B, the SiₓC_{y}N_{z} compound layer 202-1″ is disposed on the base layer 201″ and the SiₐN_{b} compound layer 202-2″ is disposed on the SiₓC_{y}N_{z} compound layer 202-1″.

In some embodiments, the anti-reflection layer has a SiₓC_{y}N_{z} compound layer and a SiₐN_{b} compound layer. The values of a, b, x, y, and z are stoichiometric ratio of elements in the SiₓC_{y}N_{z} compound layer and the SiₐN_{b} compound layer. The values of a, b, x, y, and z range from 0 to about 50. In some embodiments, a value of a and x are different with each other. In some embodiments, a value of x and y are same with each other. In some embodiments, a value of z and b are same with each other. At least one of the x, y, and z is less than 4.0. At least one of the x, y, and z is less than 1.5. At least two of the x, y, and z have the same value. At least one of the x and y is less than z. The value of x is less than z. The value of y is less than z. The value of x is less than about 1.5. The value of y is less than about 1.5. The value of z is less than about 4. In exemplary embodiment, the SiₓC_{y}N_{z} compound layer is Si_{1.5}C_{1.5}N₄ and the SiₐN_{b} compound layer is Si₃N₄.

Accordingly, one aspect of the instant disclosure provides a semiconductor structure that comprises a base layer; an anti-reflection layer having a plurality of elements and in physical contact with the base layer; and a photoresist layer disposed on the anti-reflection layer. The plurality of elements includes Silicon (Si) element, Carbon (C) element, and Nitrogen (N) element. At least one of the plurality of elements is in gradient concentration along a thickness of the anti-reflection layer.

In some embodiments, at least one of the plurality of elements is in gradient concentration along a thickness of the anti-reflection layer.

In some embodiments, a concentration of the Carbon (C) element closest to the base layer is zero and increases as the anti-reflection layer extends away from the base layer.

In some embodiments, a concentration of the Carbon (C) element farthest from the base layer is zero and increases as the anti-reflection layer extends into the base layer.

In some embodiments, a ratio between Silicon (Si) element and the Carbon (C) element (Si:C ratio) ranges from about 1:2 to about 2:1.

In some embodiments, the anti-reflection layer has a SiₓC_{y}N_{z} compound layer and a SiₐN_{b} compound layer. The values of a, b, x, y, and z are stoichiometric ratio of elements in the SiₓC_{y}N_{z} compound layer and the SiₐN_{b} compound layer. The values of a,b, x, y, and z range from 0 to about 50.

In some embodiments, a value of a and x are different with each other.

In some embodiments, a value of x and y are same with each other.

In some embodiments, a value of z and b are same with each other.

In some embodiments, the base layer is a silicon (Si) based material including at least one of a silicon layer and a silicon dioxide layer.

In some embodiments, the anti-reflection layer has a refractive index (n) ranging between about 2.2 to about 5.0.

In some embodiments, the anti-reflection layer has an extinction coefficient (k) ranging between about 2.0 to about 3.0.

Accordingly, another aspect of the instant disclosure provides a method of forming a semiconductor structure that comprises providing a base layer in a process chamber; forming an anti-reflection layer directly on the base layer, the anti-reflection layer having a plurality of elements; and forming a photoresist layer on the anti-reflection layer. The plurality of elements includes Silicon (Si) element, Carbon (C) element, and Nitrogen (N) element.

In some embodiments, the anti-reflection layer has a refractive index (n) ranging between about 2.2 to about 5.0.

In some embodiments, the anti-reflection layer has an extinction coefficient (k) ranging between about 2.0 to about 3.0.

In some embodiments, at least one of the plurality of elements is in gradient concentration along a thickness of the anti-reflection layer.

In some embodiments, forming the anti-reflection layer comprises providing a silicon (Si) source to the process chamber; providing a Nitrogen (N) source to the process chamber; and providing a Carbon (C) source to the process chamber. A percentage of the Carbon (C) source within the process chamber changes along time.

In some embodiments, the percentage of the Carbon (C) source within the process chamber increases along time to form the anti-reflection layer having a concentration of the Carbon (C) element closest to the base layer be zero and increases as the anti-reflection layer extends away from the base layer.

In some embodiments, the percentage of the Carbon (C) source within the process chamber decreases along time to form the anti-reflection layer having a concentration of the Carbon (C) element decrease as the anti-reflection layer extends away from the base layer.

In some embodiments, forming the anti-reflection layer comprises forming a SiₓC_{y}N_{z} compound layer over the base layer; and forming a SiₐN_{b} compound layer over the base layer. The values of a, b, x, y, and z are stoichiometric ratio of elements in the SiₓC_{y}N_{z} compound layer and the SiₐN_{b} compound layer. The values of a, b, x, y, and z range from 0 to about 50.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a base layer; and
an anti-reflection layer having a plurality of elements and in physical contact with the base layer;
wherein the plurality of elements includes Silicon (Si) element, Carbon (C) element, and Nitrogen (N) element.

2. The semiconductor structure of claim 1, wherein at least one of the plurality of elements is in gradient concentration along a thickness of the anti-reflection layer.

3. The semiconductor structure of claim 2, wherein a concentration of the Carbon (C) element closest to the base layer is zero and increases as the anti-reflection layer extends away from the base layer.

4. The semiconductor structure of claim 2, wherein a concentration of the Carbon (C) element farthest from the base layer is zero and increases as the anti-reflection layer extends into the base layer.

5. The semiconductor structure of claim 1, wherein a ratio between Silicon (Si) element and the Carbon (C) element (Si:C ratio) ranges from about 1:2 to about 2:1.

6. The semiconductor structure of claim 1, wherein the anti-reflection layer has a SiₓC_{y}N_{z} compound layer and a SiₐN_{b} compound layer;
wherein a,b, x, y, and z are stoichiometric ratio of elements in the SiₓC_{y}N_{z} compound layer and the SiₐN_{b} compound layer; and
wherein a,b, x, y, and z range from 0 to about 50.

7. The semiconductor structure of claim 6, wherein a value of a and x are different with each other.

8. The semiconductor structure of claim 6, wherein a value of x and y are same with each other.

9. The semiconductor structure of claim 6, wherein a value of z and b are same with each other.

10. The semiconductor structure of claim 1, wherein the base layer is a silicon (Si) based material including at least one of a silicon layer and a silicon dioxide layer.

11. The semiconductor structure of claim 1, wherein the anti-reflection layer has a refractive index (n) ranging between about 2.2 to about 5.0.

12. The semiconductor structure of claim 1, wherein the anti-reflection layer has an extinction coefficient (k) ranging between about 2.0 to about 3.0.

13. A method of forming a semiconductor structure, comprising:
providing a base layer in a process chamber; and
forming an anti-reflection layer directly on the base layer, the anti-reflection layer having a plurality of elements;
wherein the plurality of elements includes Silicon (Si) element, Carbon (C) element, and Nitrogen (N) element.

14. The method of claim 13, wherein the anti-reflection layer has a refractive index (n) ranging between about 2.2 to about 5.0.

15. The method of claim 13, wherein the anti-reflection layer has an extinction coefficient (k) ranging between about 2.0 to about 3.0.

16. The method of claim 13, wherein at least one of the plurality of elements is in gradient concentration along a thickness of the anti-reflection layer.

17. The method of claim 16, wherein forming the anti-reflection layer comprises:
providing a silicon (Si) source to the process chamber;
providing a Nitrogen (N) source to the process chamber; and
providing a Carbon (C) source to the process chamber;
wherein a percentage of the Carbon (C) source within the process chamber changes along time.

18. The method of claim 17, wherein the percentage of the Carbon (C) source within the process chamber increases along time to form the anti-reflection layer having a concentration of the Carbon (C) element closest to the base layer be zero and increases as the anti-reflection layer extends away from the base layer.

19. The method of claim 17, wherein the percentage of the Carbon (C) source within the process chamber decreases along time to form the anti-reflection layer having a concentration of the Carbon (C) element decrease as the anti-reflection layer extends away from the base layer.

20. The method of claim 13, wherein forming the anti-reflection layer comprises:
forming a SiₓC_{y}N_{z} compound layer over the base layer; and
forming a SiₐN_{b} compound layer over the base layer;
wherein a, b, x, y, and z are stoichiometric ratio of elements in the SiₓC_{y}N_{z} compound layer and the SiₐN_{b} compound layer;
wherein a, b, x, y, and z range from 0 to about 50.
